(19) United States
(12) Patent Application Publication
(10) Pub. No.: US 2019/0217573 A1
(43) Pub. Date: Jul. 18, 2019

(54) FLEXIBLE SUBSTRATE, MANUFACTURING METHOD THEREOF, AND FLEXIBLE ELECTRONIC DEVICE INCLUDING THE SAME

(71) Applicants: Postech Academy-Industry Foundation, Pohang-si (KR); Center for Advanced Soft Electronics, Pohang-si (KR)

(72) Inventors: Yoonyoung CHUNG, Busan (KR); Kilwon CHO, Pohang-si (KR); Seongmin PARK, lncheon (KR); Hyuk PARK, Seoul (KR)

(73) Assignees: Postech Academy-Industry Foundation, Pohang-si (KR); Center for Advanced Soft Electronics, Pohang-si (KR)

(21) Appl. No.: 16/248,972

(22) Filed: Jan. 16, 2019

(30) Foreign Application Priority Data
Jan. 18, 2018 (KR) 10-2018-0006773
Sep. 17, 2018 (KR) 10-2018-0111066

(51) Int. Cl. B32B 7/022; H05K 1/03; B32B 27/08; B32B 27/28; B32B 37/00; B32B 37/24

(52) U.S. Cl. CPC B32B 7/022; B32B 2457/08; B32B 27/08; B32B 27/281; B32B 27/283; B32B 37/025; B32B 37/24; H05K 2201/0154; H05K 2201/0162; B32B 2037/243; B32B 2250/03; B32B 2250/24; B32B 2305/72; B32B 2307/54; B32B 2307/546; B32B 2309/02; B32B 2379/08; B32B 2383/00; H05K 1/036

(57) ABSTRACT

Provided is a flexible substrate. The flexible substrate includes a first film having a first Young's modulus, a second film on the first film and having a second Young's modulus, and a third film between the first film and the second film and having a third Young's modulus. The third Young's modulus is less than each of the first Young's modulus and the second Young's modulus.

### CROSS-REFERENCE TO RELATED APPLICATIONS

This U.S. non-provisional patent application claims priority under 35 U.S.C. § 119 of Korean Patent Application Nos. 10-2018-0006773, filed on Jan. 18, 2018, and 10-2018-0111066, filed on Sep. 17, 2018, the entire contents of which are hereby incorporated by reference.

### BACKGROUND

The present disclosure herein relates to a flexible substrate that is applicable to various electronic devices, manufacturing method thereof, and a flexible electronic device including the same.

As a technology is developed in recent years, a flexible electronic device having flexibility has been developed. The flexible electronic device may include a display element or a memory element, which is disposed on a flexible substrate. For example, the flexible electronic device may include a display device, a mobile phone, a digital device, and an information communication device, which have flexibility. Since the flexible electronic device is flexibly bendable according to request of a user, portability and convenience of the user may be enhanced.

The flexible substrate may be mainly made of a polymer material having excellent flexibility. A surface strain that is applied to a surface of the flexible substrate when the flexible substrate is bent may be transmitted to the display element or the memory element, which is disposed on the surface of the flexible substrate. In this case, although the flexible substrate itself has high flexibility, the display element or the memory element may be degraded in electrical characteristics by the surface strain, and thus, the entire flexible electronic device may not be realized.

### SUMMARY

The present disclosure provides a flexible substrate with surface strain reduced and a manufacturing method thereof.

The present disclosure also provides a flexible electronic device capable of minimizing performance degradation due to physical bending or deformation.

An embodiment of the inventive concept may provide a flexible substrate including: a first film having a first Young's modulus; a second film disposed on the first film and having a second Young's modulus; and a third film disposed between the first film and the second film and having a third Young's modulus. The third Young's modulus may be less than each of the first Young's modulus and the second Young's modulus.

In some embodiments, the first film and the second film may include the same material as each other.

In some embodiments, the third film may include a material different from that of each of the first film and the second film.

In some embodiments, each of the first to third films may include a polymer material.

In some embodiments, each of the first to third films may include at least one selected from the group consisting of polytetrafluoroethylene (PTFE), polyimide, polyamide, polyester, polyethylene, polypropylene, polyurethane, polydimethylsiloxane (PDMS), polyacrylate, polyarylate, and fiber reinforced plastic, and a combination thereof.

In some embodiments, each of the first film and the second film may include polyimide.

In some embodiments, the third film may include polydimethylsiloxane (PDMS).

In some embodiments, the third film may have a bottom surface that directly contacts a top surface of the first film and a top surface that directly contacts a bottom surface of the second film.

In an embodiment of the inventive concept, a method for manufacturing a flexible substrate may include: forming a first film and a first preliminary layer on a first support substrate in a sequence; forming a second film and a second preliminary layer on a second support substrate in a sequence; attaching a top surface of the first preliminary layer to a top surface of the second preliminary layer; and performing a heat treatment process to cure the first preliminary layer and the second preliminary layer, thereby forming a third film. The third film may have a Young's modulus less than that of each of the first and second films.

In some embodiments, the forming of the first preliminary layer may include applying a first composition on the first film and then performing a first heat treatment process to partially cure the first composition , the forming of the second preliminary layer may include applying a second composition on the second film and then performing a second heat treatment process to partially cure the second composition, and each of the first heat treatment process and the second heat treatment process may be performed at a temperature less than that of the heat treatment process.

In some embodiments, the attaching of the top surface of the first preliminary layer to the top surface of the second preliminary layer may include: separating the second support substrate from the second film; and providing the second film and the second preliminary layer on the first support substrate so that the top surface of the second preliminary layer faces the top surface of the first preliminary layer after the second support substrate is separated.

In some embodiments, the method may further include separating the first support substrate from the first film after the third film is formed.

In some embodiments, the attaching of the top surface of the first preliminary layer to the top surface of the second preliminary layer may include:

providing the second support substrate, the second film, and the second preliminary layer on the first support substrate so that the top surface of the second preliminary layer faces the top surface of the first preliminary layer.

In some embodiments, the method may further include separating the first support substrate and the second support substrate from the first film and the second film, respectively, after the third film is formed.

In an embodiment of the inventive concept, a flexible electronic device may include: a flexible substrate; and an electronic element disposed on the flexible substrate. The flexible substrate comprises a first film, a second film disposed on the first film, and a third film disposed between the first film and the second film, and the third film may have a Young's modulus less than that of each of the first and second films.

In some embodiments, each of the first to third films may include a polymer material.

In some embodiments, the first film and the second film may include the same polymer material as each other.

In some embodiments, the third film may include a polymer material different from that of each of the first and second films.

In some embodiments, each of the first and second films may include polyimide, and the third film may include polydimethylsiloxane (PDMS).

In some embodiments, the electronic element may include at least one of a memory element, a display element, a solar cell, a light emitting diode, and a sensor.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a cross-sectional view illustrating a flexible substrate according to an embodiment of the inventive concept;

FIG. 2 is a cross-sectional view illustrating a bent state of the flexible substrate of FIG. 1;

FIGS. 3 and 4 are graphs showing surface strains of flexible substrates according to embodiments of inventive concept;

FIG. 5 is a graph showing a surface resistance variation according to the number of bending of the flexible substrate according to embodiments of the inventive concept;

FIGS. 6 and 7 are cross-sectional views illustrating a method for manufacturing the flexible substrate according to some embodiments of the inventive concept;

FIG. 8 is a cross-sectional view illustrating a method for manufacturing the flexible substrate according to some embodiments of the inventive concept;

FIGS. 9 and 11 are cross-sectional views illustrating a method for manufacturing the flexible substrate according to some embodiments of the inventive concept;

FIGS. 12 and 13 are cross-sectional views illustrating a method for manufacturing the flexible substrate according to some embodiments of the inventive concept;

FIGS. 14 and 15 are cross-sectional views illustrating a method for manufacturing the flexible substrate according to some embodiments of the inventive concept;

FIG. 16 is a cross-sectional view illustrating a method for manufacturing the flexible substrate according to some embodiments of the inventive concept; and

FIG. 17 is a cross-sectional view illustrating a flexible electronic device including the flexible substrate according to embodiments of the inventive concept.

### DETAILED DESCRIPTION

Exemplary embodiments of the present invention will be described with reference to the accompanying drawings so as to sufficiently understand constitutions and effects of the present invention. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims.

In this specification, it will also be understood that when another component is referred to as being ‘on’ one component, it can be directly on the one component, or an intervening third component may also be present. Also, in the figures, the dimensions of components are exaggerated for clarity of illustration. Like reference numerals refer to like elements throughout.

The embodiment in the detailed description will be described with sectional views and/or plain views as ideal exemplary views of the present invention. Also, in the figures, the dimensions of layers and regions are exaggerated for clarity of illustration. Areas exemplified in the drawings have general properties, and are used to illustrate a specific shape of a semiconductor package region. Thus, this should not be construed as limited to the scope of the present invention. Also, though terms like a first, a second, and a third are used to describe various regions and layers in various embodiments of the inventive concept, the regions and the layers are not limited to these terms. These terms are only used to distinguish one component from another component. Embodiments described and exemplified herein include complementary embodiments thereof.

In the following description, the technical terms are used only for explaining a specific exemplary embodiment while not limiting the inventive concept. In this specification, the terms of a singular form may include plural forms unless specifically mentioned. The meaning of “include,” “comprise,” “including,” or “comprising,” specifies a property, a region, a fixed number, a step, a process, an element and/or a component but does not exclude other properties, regions, fixed numbers, steps, processes, elements and/or components.

Hereinafter, embodiments of the present invention will be described with reference to the accompanying drawings.

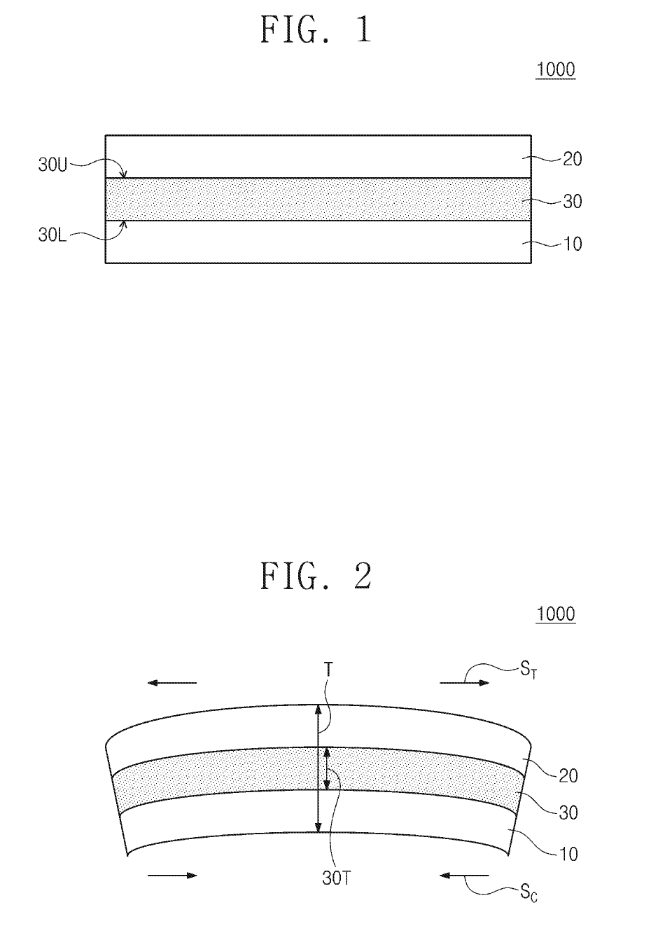

FIG. 1 is a cross-sectional view illustrating a flexible substrate according to an embodiment of the inventive concept.

Referring to FIG. 1, a flexible substrate 1000 may include a first film 10, a second film 20 on the first film 10, and a third film 30 between the first film 10 and the second film 20. The third film 30 may have a bottom surface 30L that directly contacts a top surface of the first film 10 and a top surface 30U that directly contacts a bottom surface of the second film 20. The first film 10 may have a first Young's modulus, and the second film 20 may have a second Young's modulus. In some embodiments, the first Young's modulus may be the same as the second Young's modulus. In other embodiments, the first Young's modulus may be different from the second Young's modulus. The third film 30 may have a third Young's modulus that is less than each of the first Young's modulus and the second Young's modulus.

Each of the first to third films 10, 20, and 30 may include a polymer material. Each of the first film 10 and the second film 20 may include a polymer material having a Young's modulus greater than that of the third film 30, and the third film 30 may include a polymer material having a Young's modulus less than that of each of the first film 10 and the second film 20. Each of the first to third films 10, 20, and 30 may include at least one selected from the group consisting of polytetrafluoroethylene (PTFE), polyimide, polyamide, polyester, polyethylene, polypropylene, polyurethane, polydimethylsiloxane (PDMS), polyacrylate, polyarylate, and fiber reinforced plastic, and a combination thereof.

The first film 10 and the second film 20 may include the same material as each other, and the third film 30 may include a material different from that of each of the first film 10 and the second film 20. For example, the first film 10 and the second film 20 may include the same polymer material as each other, and the third film 30 may include a polymer material different from that of each of the first film 10 and the second film 20. For example, each of the first film 10 and the second film 20 may include polyimide, and the third film 30 may include polydimethylsiloxane (PDMS).

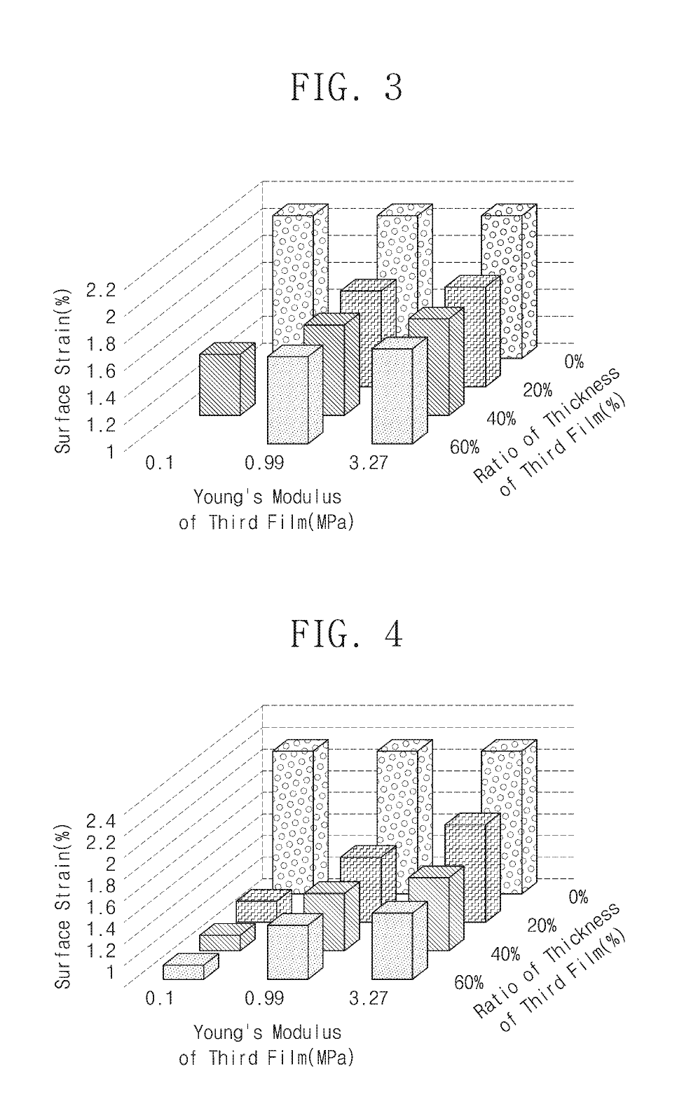

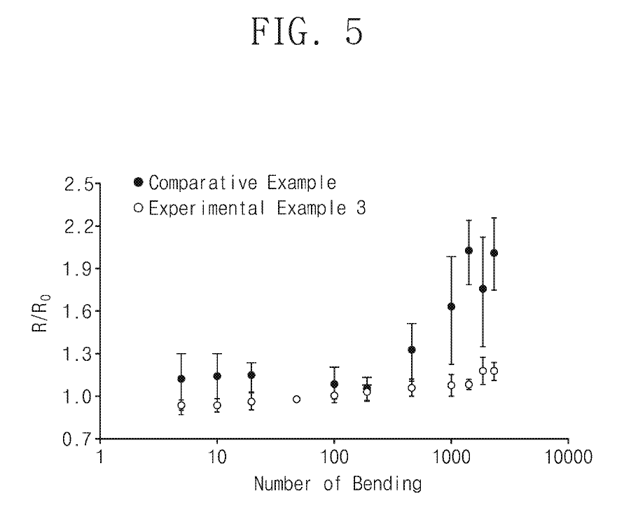

FIG. 2 is a cross-sectional view illustrating a bent state of the flexible substrate of FIG. 1. FIGS. 3 and 4 are graphs showing surface strains of flexible substrates according to embodiments of inventive concept. FIG. 5 is a graph showing a sheet resistance variation of .a conductor on the flexible substrate exemplified in FIG. 1 according to the number of bending of the flexible substrate according to embodiments of the inventive concept.

Referring to FIG. 2, when the flexible substrate 1000 is bent, a tensile strain ST may be applied to one surface of the flexible substrate 1000, and a compressive strain SC may be applied to the other surface of the flexible substrate 1000. The tensile strain ST or the compressive strain SC, which is applied to the surface of the flexible substrate 1000, may be referred to as a surface strain. According to an embodiment of the inventive concept, as the third film 30 has a Young's modulus less than that of each of the first and second films 10 and 20, at least a portion of the surface strain that is applied to the flexible substrate 1000 may be reduced by inserting the third film 30. Accordingly, the surface strain of the flexible substrate 1000 may be reduced.

The surface strain of the flexible substrate 1000 may be controlled according to a ratio of a thickness 30T of the third film 30 with respect to an entire thickness T of the flexible substrate 1000 and variation on the third Young's modulus of the third film 30. Hereinafter, in an experimental example 1 and an experimental example 2, the surface strain according to the bending of the flexible substrate 1000 is calculated by using a finite element method (FEM) simulation. The surface strain of the flexible substrate is calculated according to i) the ratio of the thickness 30T of the third film 30 and ii) the variation of the third Young's modulus of the third film 30.

### Experimental Example 1

It is assumed that a total thickness T of the flexible substrate 1000 is about 20 μm, and the flexible substrate 1000 is bent with a curvature radius of about 1 mm. The first film 10 and the second film 20 are applied with a property of polyimide, and the third film 30 is applied with a property of polydimethylsiloxane (PDMS). The ratio of the thickness 30T of the third film 30 is changed to 0%, 20%, 40%, and 60%, and the third Young's modulus of the third film 30 is changed to 0.1 MPa, 0.99 MPa and 3.27 MPa.

TABLE 1
Surface strain (%)

Young's modulus of third film (MPa)

| | | 0.1 | 0.99 | 3.27 |
|---|---|---|---|---|
| Ratio of | 0 | 2.03 | 2.03 | 2.03 |
| thickness of | 20 | — | 1.6922 | 1.7172 |
| third film (%) | 40 | 1.4378 | 1.6407 | 1.6777 |
| | 60 | — | 1.6 | 1.656 |

FIG. 3 is a graph showing variation of the surface strain of the flexible substrate 1000 according to the experimental example 1 while illustrating results of table 1. Referring to FIG. 3, as the ratio of the thickness 30T of the third film 30 increases, and the third Young's modulus of the third film 30 decreases, the surface strain of the flexible substrate 1000 is gradually reduced.

### Experimental Example 2

It is assumed that the total thickness T of the flexible substrate 1000 is about 100 μm, and the flexible substrate 1000 is bent with a curvature radius of about 5 mm. The first film 10 and the second film 20 are applied with the property of polyimide, and the third film 30 is applied with the property of polydimethylsiloxane (PDMS). The ratio of the thickness 30T of the third film 30 is changed to 0%, 20%, 40%, and 60%, and the third Young's modulus of the third film 30 is changed to 0.1 MPa, 0.99 MPa and 3.27 MPa.

TABLE 2
Surface strain (%)

Young's modulus of third film (MPa)

| | | 0.1 | 0.99 | 3.27 |
|---|---|---|---|---|
| Ratio of | 0 | 2.236 | 2.236 | 2.236 |
| thickness of | 20 | 1.216 | 1.57 | 1.818 |
| third film (%) | 40 | 1.148 | 1.483 | 1.614 |
| | 60 | 1.11 | 1.45 | 1.54 |

FIG. 4 is a graph showing variation of the surface strain of the flexible substrate 1000 according to the experimental example 2 while illustrating results of table 2. Referring to FIG. 4, as the ratio of the thickness 30T of the third film 30 increases, and the third Young's modulus of the third film 30 decreases, the surface strain of the flexible substrate 1000 is gradually reduced.

According to an embodiment of the inventive concept, the flexible substrate 1000 may be configured to minimize the surface strain, which is applied thereto, when the flexible substrate 1000 is bent. Due to this, even when the bending of the flexible substrate 1000 is repeated by a plurality of times, variation of the surface resistance of the flexible substrate 1000 may be minimized. Hereinafter, in an experimental example 3, a variation rate of the sheet resistance of the conductor on the flexible substrate 1000 according to the number of the bending of the flexible substrate 1000 will be verified.

### Experimental Example 3

A multilayer flexible substrate, in which polyimide (thickness of about 20 μm)/PDMS (thickness of about 40 μm)/polyimide (thickness of about 20 μm) are laminated, is prepared. An indium tin oxide (ITO) thin-film having a thickness of about 100 nm is deposited on the multilayer flexible substrate. A tensile strain is applied to the ITO thin-film by bending and unbending the multilayer flexible substrate with a curvature radius of about 6 mm in a repeated manner Variation of resistances of the ITO thin-film is measured.

### Comparative Example

A single-layer flexible substrate of polyimide (thickness of about 80 μm) is prepared. An indium tin oxide (ITO) thin-film having a thickness of about 100 nm is deposited on the single-layer flexible substrate. A tensile strain is applied to the ITO thin-film by bending and unbending the single-layer flexible substrate with a curvature radius of about 6 mm in a repeated manner Variation of resistances of the ITO thin-film is measured

In FIG. 5, at a vertical axis, R0 represents an initial resistance, and R represents a resistance that is measured after a process of bending and unbending the flexible substrate of the experimental example 3 or the comparative example is repeated. In FIG. 5, a horizontal axis represents the repeated number of the process of bending and unbending the flexible substrate of the experimental example 3 or the comparative example. Referring to FIG. 5, when the process of bending and unbending the single-layer flexible substrate of the comparative example is repeated by about 200 times or more, it may be seen that the variation rate of the sheet resistance of the ITO thin-film on the single-layer flexible substrate remarkably increases. In the case of the multilayer flexible substrate of the experimental example 3, although the process of bending and unbending the multilayer flexible substrate is repeated by about 2000 times, a variation rate of the sheet resistance of the ITO thin-film on the multilayer flexible substrate may be maintained at about 30% or less. That is, the resistance variation of the ITO thin-film on the multilayer flexible substrate may relatively decrease.

According to an embodiment of the inventive concept, the flexible substrate 1000 may include the third film 30 disposed between the first film 10 and the second film 20 and having a Young's modulus less than that of each of the first and second films 10 and 20. Accordingly, when the flexible substrate 1000 is bent, the surface strain applied to the flexible substrate 1000 may be reduced. In addition, according to an embodiment of the inventive concept, when the flexible substrate 1000 is bent, the surface strain applied to the flexible substrate 1000 may be controlled to be less than a threshold value by adjusting the ratio of the thickness 30T of the third film 30 with respect to the entire thickness T of the flexible substrate 1000 and the third Young's modulus of the third film 30. Resultantly, variations of the electrical characteristics of the electronic element (e.g., a resistance variation of the ITO thin-film) provided on the flexible substrate 1000 may be minimized. Here, the threshold value represents a maximum value of the surface strain, which is capable of maintaining required performance of the electronic element.

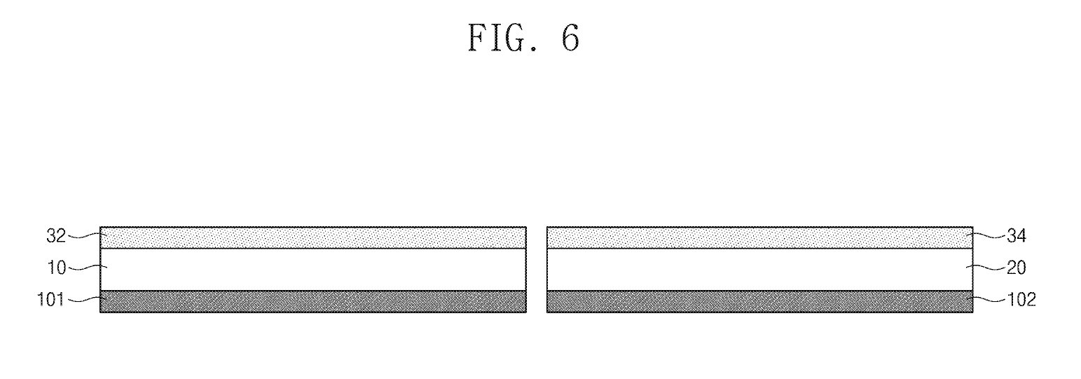

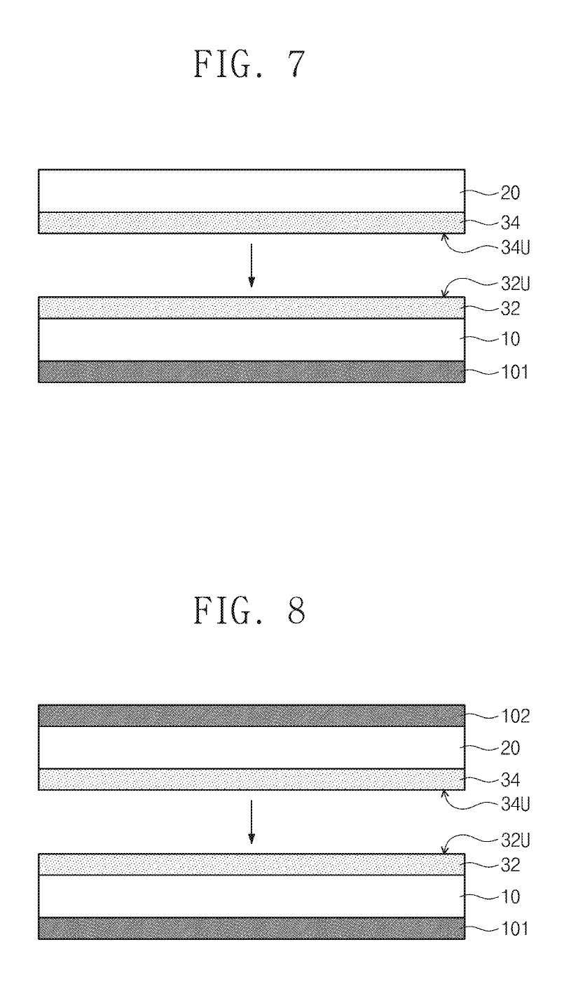

FIGS. 6 and 7 are cross-sectional views illustrating a method for manufacturing the flexible substrate according to some embodiments of the inventive concept. For simplicity of description, duplicate description with that of the flexible substrate according to embodiments of the inventive concept with reference to FIGS. 1 to 5 will be omitted.

Referring to FIG. 6, the first film 10 may be formed on a first support substrate 101. The first support substrate 101 may be, e.g., a silicon wafer or a glass wafer. The first film 10 may be formed by applying a first film composition on the first support substrate 101 and then thermally curing the first film composition. The first film composition may be, e.g., a polyimide solution. The applying of the first film composition may be performed through methods such as spin coating, bar coating, blade coating, and pouring. A first preliminary layer 32 may be formed on the first film 10. The forming of the first preliminary layer 32 may include: applying a first composition on the first film 10; and performing a first heat treatment process to partially cure the first composition. The first composition may be, e.g., a polydimethylsiloxane (PDMS) solution. The applying of the first composition may be performed through methods such as spin coating, bar coating, blade coating, and pouring. When the first preliminary layer 32 includes polydimethylsiloxane (PDMS), and the first heat treatment process may be performed, e.g., at a temperature of about 60° C. during about 30 minutes to about 40 minutes. As the first composition is partially cured, the first preliminary layer 32 may has a solid shape in a viscous state.

The second film 20 may be formed on a second support substrate 102. The second support substrate 102 may be, e.g., a silicon wafer or a glass wafer. The second film 20 may be formed by applying a second film composition on the second support substrate 102 and then thermally curing the second film composition. The second film composition may be, e.g., a polyimide solution. The applying of the second film composition may be performed through methods such as spin coating, bar coating, blade coating, and pouring. A second preliminary layer 34 may be formed on the second film 20. The forming of the second preliminary layer 34 may include: applying a second composition on the second film 20; and performing a second heat treatment process to partially cure the second composition. The second composition may be, e.g., a polydimethylsiloxane (PDMS) solution. The applying of the second composition may be performed through methods such as spin coating, bar coating, blade coating, and pouring. When the second preliminary layer 34 includes polydimethylsiloxane (PDMS), and the second heat treatment process may be performed, e.g., at a temperature of about 60° C. during about 30 minutes to about 40 minutes. As the second composition is partially cured, the second preliminary layer 34 may has a solid shape in a viscous state.

Referring to FIG. 7, the second support substrate 102 may be removed from the second film 20. The removing of the second support substrate 102 may include physically separating the second support substrate 102 from the second film 20. After the second support substrate 102 is removed, the second film 20 and the second preliminary layer 34 may be provided on the first preliminary layer 32 so that a top surface 32U of the first preliminary layer 32 faces a top surface 34U of the second preliminary layer 34. The top surface 32U of the first preliminary layer 32 and the top surface 34U of the second preliminary layer 34 may be attached to each other, and then a third heat treatment process may be performed. The third heat treatment process may be performed at a temperature higher than the first heat treatment process and the second heat treatment process. For example, when each of the first and second preliminary layers 32 and 34 includes polydimethylsiloxane (PDMS), the third heat treatment process may be performed at a temperature of about 120° C. during about 30 minutes. As the first preliminary layer 32 and the second preliminary layer 34 are cured by the third heat treatment process, the third film 30 in FIG. 1 may be formed. Accordingly, the flexible substrate 1000 in FIG. 1 may be manufactured.

FIG. 8 is a cross-sectional view illustrating a method for manufacturing the flexible substrate according to some embodiments of the inventive concept. For simplicity of description, the difference from the method for manufacturing the flexible substrate with reference to FIGS. 6 and 7 will be mainly described.

As described with reference to FIG. 6, the first film 10 and the first preliminary layer 32 may be sequentially formed on the first support substrate 101, and the second film 20 and the second preliminary layer 34 may be sequentially formed on the second support substrate 102.

Referring to FIG. 8, the second support substrate 102, the second film 20, and the second preliminary layer 34 may be provided on the first preliminary layer 32 so that the top surface 32U of the first preliminary layer 32 faces the top surface 34U of the second preliminary layer 34. The top surface 32U of the first preliminary layer 32 and the top surface 34U of the second preliminary layer 34 may be attached to each other, and then the third heat treatment process may be performed. The third heat treatment process may be performed at a temperature higher than the first heat treatment process and the second heat treatment process. As the first preliminary layer 32 and the second preliminary layer 34 are cured by the third heat treatment process, the third film 30 in FIG. 1 may be formed. Thereafter, the first support substrate 101 and the second support substrate 102 may be removed from the first film 10 and the second film 20, respectively. The removing of the first and second support substrates 101 and 102 may include physically separating the first and second support substrates 101 and 102 from the first and second films 10 and 20. Accordingly, the flexible substrate 1000 in FIG. 1 may be manufactured.

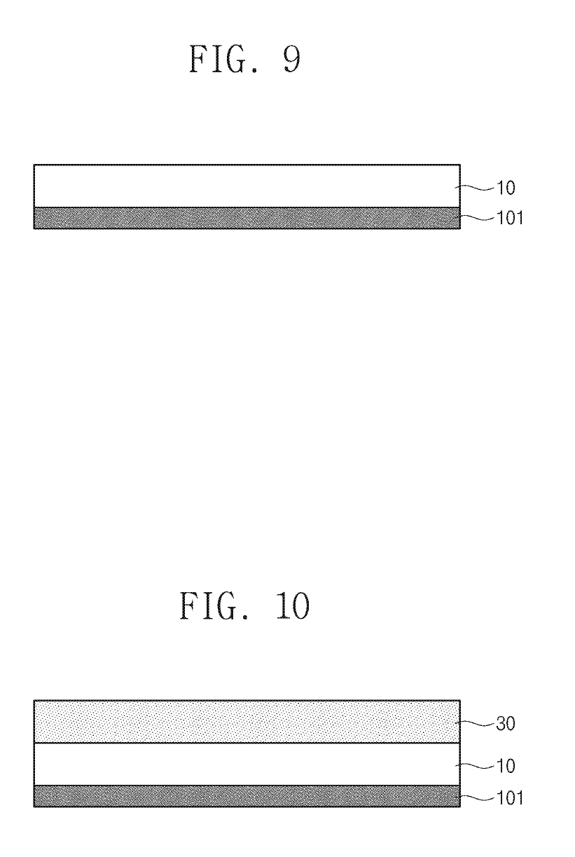

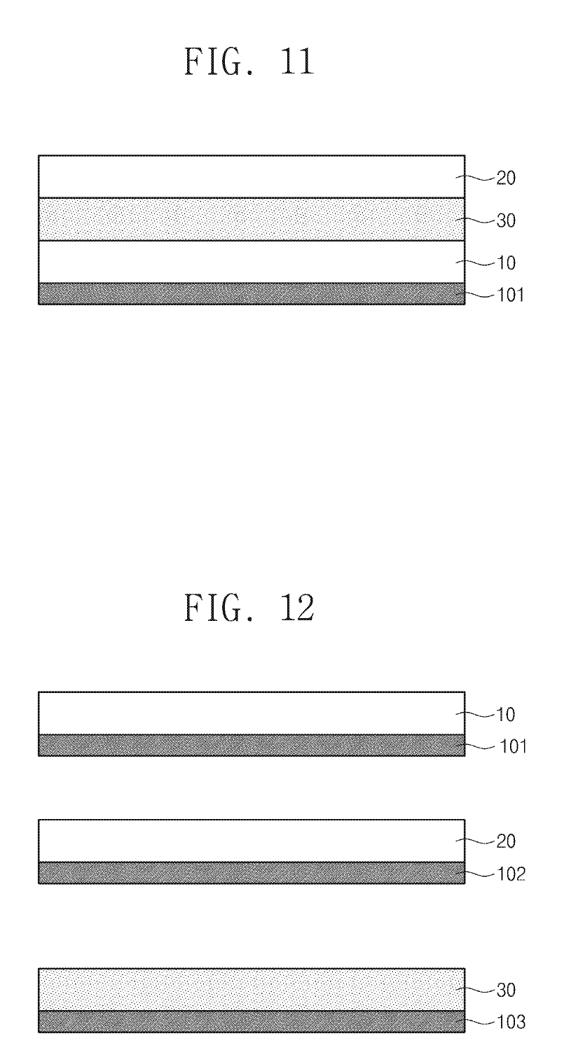

FIGS. 9 and 11 are cross-sectional views illustrating a method for manufacturing the flexible substrate according to some embodiments of the inventive concept. For simplicity of description, the difference from the method for manufacturing the flexible substrate with reference to FIGS. 6 and 7 will be mainly described.

Referring to FIG. 9, the first film 10 may be formed on the first support substrate 101. The first film 10 may be formed by applying the first film composition on the first support substrate 101 and then thermally curing the first film composition. According to the embodiments, the thermal curing of the first film composition may be performed at a relatively low temperature. For example, the first film 10 may include low temperature curable polyimide.

Referring to FIG. 10, the third film 30 may be formed on the first film 10. The third film 30 may be formed by applying a third film composition on the first film 10 and then thermally curing the third film composition. The third film composition may be, e.g., a polydimethylsiloxane (PDMS) solution. The applying of the third film composition may be performed through methods such as spin coating, bar coating, blade coating, and pouring.

Referring to FIG. 11, the second film 20 may be formed on the third film 30. The second film 20 may be formed by applying the second film composition on the third film 30 and then thermally curing the second film composition. According to the embodiments, the thermal curing of the second film composition may be performed at a relatively low temperature. For example, the second film 20 may include low temperature curable polyimide. According to the embodiments, the first film 10, the third film 30, and the second film 20 may be sequentially formed on the first support substrate 101. Thereafter, the first support substrate 101 may be removed from the first film 10. The removing of the first support substrate 101 may include physically separating the first support substrate 101 from the first film 10. Accordingly, the flexible substrate 1000 in FIG. 1 may be manufactured.

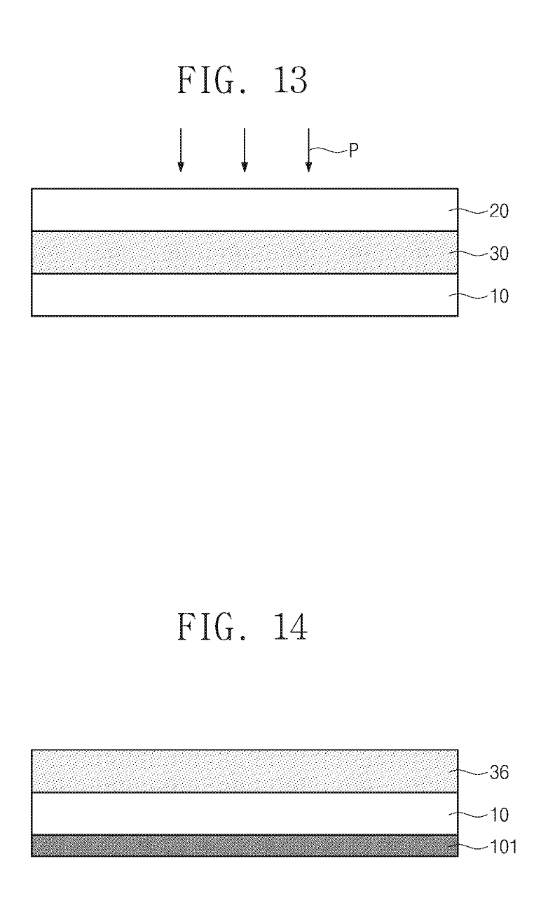

FIGS. 12 and 13 are cross-sectional views illustrating a method for manufacturing the flexible substrate according to some embodiments of the inventive concept. For simplicity of description, the difference from the method for manufacturing the flexible substrate with reference to FIGS. 6 and 7 will be mainly described.

Referring to FIG. 12, the first film 10 and the second film 20 may be formed on the first support substrate 101 and the second support substrate 102, respectively. The first film 10 and the second film 20 may be formed by the substantially same method as the method described with reference to FIG. 6. Thereafter, the first support substrate 101 and the second support substrate 102 may be removed from the first film 10 and the second film 20, respectively. The removing of the first and second support substrates 101 and 102 may include physically separating the first and second support substrates 101 and 102 from the first and second films 10 and 20.

According to the embodiments, the third film 30 may be formed on a third support substrate 103. The third support substrate 103 may be, e.g., a silicon wafer or a glass wafer. The third film 30 may be formed by applying a third film composition on the third support substrate 103 and then thermally curing the third film composition. The third film composition may be, e.g., a polydimethylsiloxane (PDMS) solution. The applying of the third film composition may be performed through methods such as spin coating, bar coating, blade coating, and pouring. The third film 30 may be formed, and then the third support substrate 103 may be removed from the third film 30. The removing of the third support substrate 103 may include physically separating the third support substrate 103 from the third film 30.

Referring to FIG. 13, after the first to third support substrates 101, 102, and 103 are removed, the first to third films 10, 20, and 30 may be laminated so that the third film 30 is disposed between the first film 10 and the second film 20. A pressure P may be applied on the laminated first to third films 10, 20, and 30. For example, a pressure roller may apply the pressure P on the laminated first to third films 10, 20, and 30. Accordingly, the third film 30 may be re-cured, and, as a result, the flexible substrate 1000 of FIG. 1 may be manufactured.

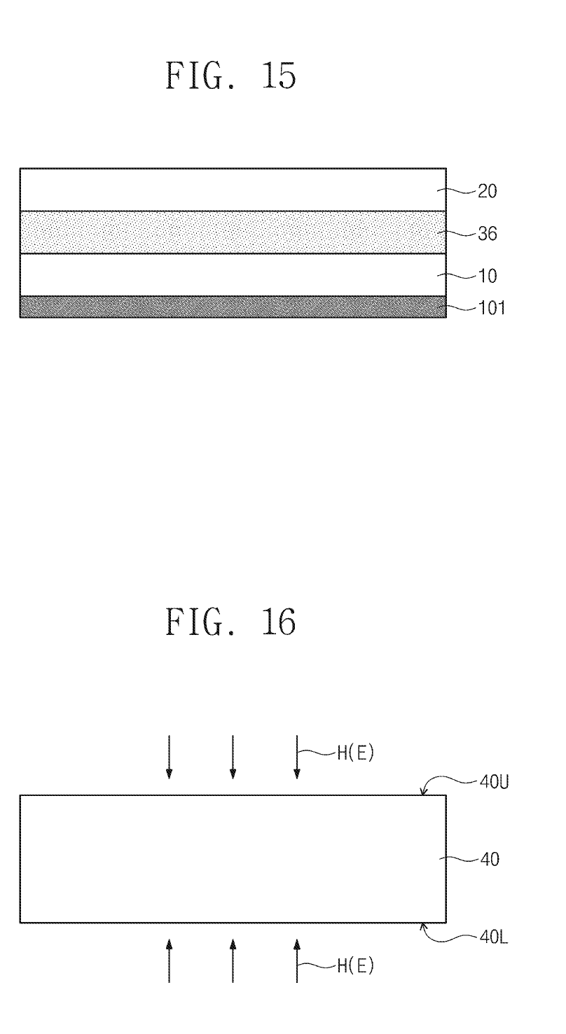

FIGS. 14 and 15 are cross-sectional views illustrating a method for manufacturing the flexible substrate according to some embodiments of the inventive concept. For simplicity of description, the difference from the method for manufacturing the flexible substrate with reference to FIGS. 6 and 7 will be mainly described.

Referring to FIG. 14, the first film 10 may be provided on the first support substrate 101. For example, the first film 10 may be formed by the substantially same method as that described with reference to FIG. 6. For another example, the first film 10, which is prepared separately from the first support substrate 101, may be attached to the first support substrate 101 so that the first film 10 is fixed to the first support substrate 101. A third film composition 36 may be applied on the first film 10. The third film composition 36 may be, e.g., a polydimethylsiloxane (PDMS) solution. The applying of the third film composition 36 may be performed through methods such as spin coating, bar coating, blade coating, and pouring.

Referring to FIG. 15, the second film 20, which is separately prepared, may be provided on the first support substrate 101 on which the third film composition 36 is applied. The second film 20 may be provided to cover the third film composition 36. Thereafter, a heat treatment process may be performed to cure the third film composition 36. Accordingly, the third film 30 of FIG. 1 may be formed. After the third film 30 is formed, the first support substrate 101 may be removed and the flexible substrate 1000 of FIG. 1 may be manufactured.

FIG. 16 is a cross-sectional view illustrating a method for manufacturing the flexible substrate according to some embodiments of the inventive concept. For simplicity of description, the difference from the method for manufacturing the flexible substrate with reference to FIGS. 6 and 7 will be mainly described.

Referring to FIG. 16, a single-layer flexible substrate 40 may be provided. The single-layer flexible substrate 40 may include a polymer material having a predetermined Young's modulus. The single-layer flexible substrate 40 may include at least one selected from the group consisting of polytetrafluoroethylene (PTFE), polyimide, polyamide, polyester, polyethylene, polypropylene, polyurethane, polydimethylsiloxane (PDMS), polyacrylate, polyarylate, and fiber reinforced plastic, and a combination thereof.

According to the embodiments, heat H or an electric field E may be provided to a top surface 40U and a bottom surface 40L of the single-layer flexible substrate 40. A Young's modulus of each of upper and lower portions of the single-layer flexible substrate 40 may be changed by the heat H or the electric field E. The Young's modulus of each of the upper and lower portions of the single-layer flexible substrate 40 may be changed to be greater than that of an intermediate portion of the single-layer flexible substrate 40. Accordingly, the flexible substrate 1000 in FIG. 1 may be manufactured.

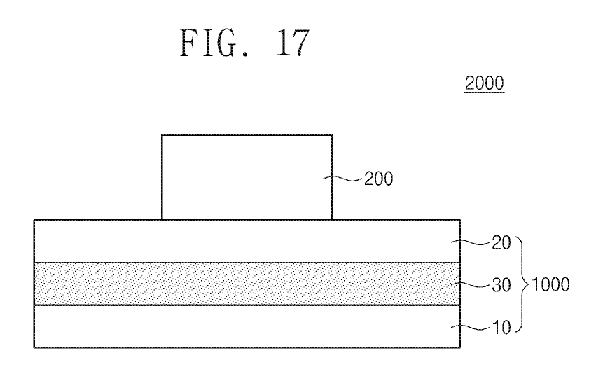

FIG. 17 is a cross-sectional view illustrating a flexible electronic device including the flexible substrate according to embodiments of the inventive concept.

Referring to FIG. 17, a flexible electronic device 2000 may include the flexible substrate 1000 of FIG. 1 and an electronic element 200 on the flexible substrate 1000. The electronic element 200 may include at least one of a memory element, a display element, a solar cell, a light emitting diode, and a sensor, however, the embodiment of the inventive concept is not limited thereto. The electronic element 200 may be made of an electronic material such as a conductor, a semiconductor, and/or a nonconductor. According to an embodiment of the inventive concept, when the flexible substrate 1000 is bent, the surface strain applied to the flexible substrate 1000 may be reduced. Accordingly, even when the flexible substrate 1000 is bent, an external force (e.g., the surface strain) applied to the electronic element 200 on the flexible substrate 1000 may be reduced. Thus, variation of electrical characteristics of the electronic element 200 may be minimized, and, as a result, the stable flexible electronic device 2000 capable of minimizing performance degradation due to physical bending or deformation may be provided.

According to the embodiment of the inventive concept, the flexible substrate may include the first film, the second film, and the third film disposed therebetween, and the third film may include a material having a Young's modulus less than that of each of the first and second films. Accordingly, when the flexible substrate is bent, the surface strain applied to the flexible substrate may be reduced, and the external force applied to the electronic element disposed on the flexible substrate may be reduced. Thus, the stable flexible electronic device capable of minimizing performance degradation due to physical bending or deformation may be provided.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A flexible substrate comprising:
a first film having a first Young's modulus;
a second film on the first film and having a second Young's modulus; and
a third film between the first film and the second film and having a third Young's modulus,
wherein the third Young's modulus is less than each of the first Young's modulus and the second Young's modulus.

2. The flexible substrate of claim 1, wherein the first film and the second film comprises the same material as each other.

3. The flexible substrate of claim 2, wherein the third film comprises a material different from that of each of the first film and the second film.

4. The flexible substrate of claim 1, wherein each of the first to third films comprises a polymer material.

5. The flexible substrate of claim 4, wherein each of the first to third films comprises at least one selected from the group consisting of polytetrafluoroethylene (PTFE), polyimide, polyamide, polyester, polyethylene, polypropylene, polyurethane, polydimethylsiloxane (PDMS), polyacrylate, polyarylate, and fiber reinforced plastic, and a combination thereof.

6. The flexible substrate of claim 4, wherein each of the first film and the second film comprises polyimide.

7. The flexible substrate of claim 4, wherein the third film comprises polydimethylsiloxane (PDMS).

8. The flexible substrate of claim 1, wherein the third film has a bottom surface that directly contacts a top surface of the first film and a top surface that directly contacts a bottom surface of the second film.

9. A method for manufacturing a flexible substrate, the method comprising:
forming a first film and a first preliminary layer on a first support substrate in a sequence;
forming a second film and a second preliminary layer on a second support substrate in a sequence;
attaching a top surface of the first preliminary layer to a top surface of the second preliminary layer; and
performing a heat treatment process to cure the first preliminary layer and the second preliminary layer, thereby forming a third film,
wherein the third film has a Young's modulus less than that of each of the first and second films.

10. The method of claim 9, wherein the forming of the first preliminary layer comprises applying a first composition on the first film and then performing a first heat treatment process to partially cure the first composition,
the forming of the second preliminary layer comprises applying a second composition on the second film and then performing a second heat treatment process to partially cure the second composition, and
each of the first heat treatment process and the second heat treatment process is performed at a temperature less than that of the heat treatment process.

11. The method of claim 9, wherein the attaching of the top surface of the first preliminary layer to the top surface of the second preliminary layer comprises:
separating the second support substrate from the second film; and
providing the second film and the second preliminary layer on the first support substrate so that the top surface of the second preliminary layer faces the top surface of the first preliminary layer after the second support substrate is separated.

12. The method of claim 11, further comprising separating the first support substrate from the first film after the third film is formed.

13. The method of claim 9, wherein the attaching of the top surface of the first preliminary layer to the top surface of the second preliminary layer comprises:
providing the second support substrate, the second film, and the second preliminary layer on the first support substrate so that the top surface of the second preliminary layer faces the top surface of the first preliminary layer.

14. The method of claim 13, further comprising separating the first support substrate and the second support substrate from the first film and the second film, respectively, after the third film is formed.

15. A flexible electronic device comprising:
a flexible substrate; and
an electronic element on the flexible substrate,
wherein the flexible substrate comprises a first film, a second film on the first film, and a third film between the first film and the second film, and
the third film has a Young's modulus less than that of each of the first and second films.

16. The flexible electronic device of claim 15, wherein each of the first to third films comprises a polymer material.

17. The flexible electronic device of claim 16, wherein the first film and the second film comprises the same polymer material as each other.

18. The flexible electronic device of claim 16, wherein the third film comprises a polymer material different from that of each of the first and second films.

19. The flexible electronic device of claim 16, wherein each of the first and second films comprises polyimide, and
the third film comprises polydimethylsiloxane (PDMS).

20. The flexible electronic device of claim 15, wherein the electronic element comprises at least one of a memory element, a display element, a solar cell, a light emitting diode, and a sensor.
